(19) United States
(12) Patent Application Publication
(10) Pub. No.: US 2008/0030191 A1
(43) Pub. Date: Feb. 7, 2008

(54) MAGNETIC SENSOR CIRCUIT, SEMICONDUCTOR DEVICE, AND MAGNETIC SENSOR DEVICE

(75) Inventor: Hidetoshi Nishikawa, Kyoto (JP)

Correspondence Address: FISH & RICHARDSON P.C., P.O. BOX 1022, MINNEAPOLIS, MN, 55440-1022, US

(73) Assignee: ROHM CO., LTD., Kyoto (JP)

(21) Appl. No.: 11/828,216

(22) Filed: Jul. 25, 2007

(30) Foreign Application Priority Data
Jul. 26, 2006 (JP) 2006-203592

(51) Int. Cl. G01R 33/02

(52) U.S. Cl. 324/252; 324/244

(57) ABSTRACT

A magnetic sensor circuit has Hall devices 10X and 10Y, selection switch circuits 20X and 20Y, amplifier units 30X ad 30Y, a comparison unit 60, capacitors 41X, 42X, 41Y, and 42Y, and switch circuits 51 and 52. The Hall voltages obtained from the Hall devices 10X and 10Y are outputted in either of a first and a second states switched by the selection switch circuits 20X and 20Y. The amplifier units 30X ad 30Y each operate differentially and, if the difference between their outputs is greater than a set hysteresis width, the output logic of a detection signal Sdet is shifted. This configuration helps reduce the influence of device offset voltages in the Hall devices, and also helps reduce the influence of input offset voltages arising in the amplifiers.

This application is based on Japanese Patent Application No. 2006-203592 filed on Jul. 26, 2006, the contents of which are hereby incorporated by reference.

### BACKGROUND OF THE INVENTION

1. Field of the Invention

The present invention relates to a magnetic sensor circuit that amplifies with an amplifier an output voltage of a Hall device, magnetic resistive device, or the like to detect magnetism at the site at which it is placed, in order to output a magnetism detection signal. The present invention also relates to a semiconductor device having such a magnetic sensor circuit integrated into it, and to a magnetic sensor device employing such a semiconductor device.

2. Description of Related Art

Typically, a magnetic sensor circuit comprises a Hall device that outputs an output voltage proportional to the intensity of a magnetic field, an amplifier that amplifies the output voltage of the Hall device, and a comparator that compares the output voltage of the amplifier with a reference voltage to output the result of the comparison; the magnetic sensor circuit outputs a binary signal that is either at high (H) or low (L) level at a time according to whether or not the intensity of the magnetic field in which the magnetic field sensor is placed is more intense than a given level.

To obtain an accurate comparison result that reflects the intensity of the magnetic field, it is necessary to reduce the offset signal component contained in the signal outputted from the amplifier to reduce the variation of this signal. Main factors that produce the offset signal component here are the offset signal component contained in the output voltage of the Hall device (hereinafter called the “device offset voltage”) and the offset signal component present at the input terminal of the amplifier (hereinafter called the “input offset voltage”). The device offset voltage is produced chiefly by stress or the like that the Hall device proper receives from its package. On the other hand, the input offset voltage is produced chiefly by variations or the like in the characteristics of the devices that form the input circuit of the amplifier.

A magnetic field sensor that is less affected by such offset voltages is disclosed in Patent Document 1 listed below. This magnetic field sensor comprises a Hall device that is, like the Hall device 1 shown in FIG. 11, typically formed as a plate having a shape that is geometrically equivalent with respect to four terminals A, C, B, and D. Here, a geometrically equivalent shape denotes one, like the shape of the Hall device 1, whose shape in one orientation is identical with its shape in a 90 degrees rotated orientation (rotated such that diagonal A-C now lies where diagonal B-D lied before). In this Hall device 1, between the voltage that appears across terminals B and D when a supply voltage is applied across terminals A and C and the voltage that appears across terminals A and C when the supply voltage is applied across terminals B and D, the effective signal components contained respectively in them—the components commensurate with the intensity of the magnetic field—are in phase, whereas the device offset voltages contained respectively in them are in opposite phases.

First, in a first period, through a switch circuit 2, the supply voltage is applied across terminals A and C of the Hall device 1, and the voltage across terminals B and D is fed to a voltage amplifier 3. Thus, the voltage amplifier 3 outputs a voltage V1 proportional to the sum of the voltage across terminals B and D and the input offset voltage of the voltage amplifier 3. Moreover, in this first period, a switch 5 is closed, so that a capacitor 4 is charged up to the voltage V1.

Subsequently, in a second period, through the switch circuit 2, the supply voltage is applied across terminals B and D of the Hall device 1, and the voltage across terminals C and A is fed to the voltage amplifier 3 with the opposite polarity to that in the first period. Thus, the voltage amplifier 3 outputs a voltage V2 proportional to the sum of the voltage across terminals C and A and the input offset voltage of the voltage amplifier 3.

Here, irrespective of the polarity of the input voltage, the influence of the input offset voltage remains the same as in the first period. Accordingly, the voltage V2 from the voltage amplifier 3 is proportional to the sum of the voltage across terminals C and A—a voltage of the opposite polarity to that in the first period—and the input offset voltage.

Moreover, in this second period, the switch 5 is open, so that the inverting and non-inverting output terminals 3a and 3b of the voltage amplifier 3 and the capacitor 4 are connected in series between output terminals 6 and 7. Here, the charge voltage of the capacitor 4 remains unchanged from, and is thus held equal to, the output voltage V1 of the voltage amplifier 3 in the first period. The voltage between the output terminals 6 and 7 (the output voltage of the magnetic field sensor) equals the sum of the voltage V2 at the non-inverting output terminal 3b of the voltage amplifier 3 relative to that at its inverting output terminal 3a and the voltage −V1 at one end 4a of the capacitor 4 relative to that at its other end 4b, that is, the voltage V2 minus the voltage V1. In this way, the influence of the input offset voltage is canceled out, and thus the magnetic field sensor yields as its output voltage a voltage V free from it.

Also conventionally known is a magnetic field sensor that not only is less affected by the device offset voltage but also is less affected by the input offset voltage arising in the amplifier, as disclosed in Patent Document 2 listed below. This magnetic field sensor comprises a Hall device, a switch circuit, a voltage-current converter-amplifier, a capacitor as a memory device, a switch, and a resistor.

As related technologies, one whereby a plurality of Hall devices are formed in a single silicon substrate is disclosed and proposed, for example, in Patent Document 3 listed below, and one whereby a sensor output is given hysteresis is disclosed and proposed, for example, in Patent Document 4 listed below.

Patent Document 1: Japanese Patent Registered No. 3315397, Specification;

Patent Document 2: JP-A-H08-201491

Patent Document 3: JP-A-S63-079386

Patent Document 4: JP-A-H04-271513

Patent Document 5: JP-A-H10-170533

It is true that the magnetic field sensor of Patent Document 1 can execute offset cancellation properly in an ideal condition. In reality, however, the combination of the capacitor 4 and the voltage amplifier 3 does not promise perfectly differential operation. As a result, for example, delay (bluntness) caused by the capacitor 4, or ripples or noise in the supply voltage, may prevent satisfactory execution of offset cancellation.

The magnetic field sensor of Patent Document 2 requires two voltage-current converter-amplifiers, two capacitors, and four switches. Inconveniently, this makes it difficult to realize with a small circuit scale the circuit for reducing the influence of the input offset voltage.

Patent Document 3 discloses nothing about offset canceling as described above, and therefore, avoiding the influence of the device offset voltage and the input offset voltage requires repair, stress management, etc.

The applicant of the present invention once proposed a related technology (FIGS. 1 to 5) in Japanese Patent Application No. 2005-230781 (a domestic application claiming the priority date based on a prior domestic application No. 2005-031715). This technology, however, is directed to a configuration that can handle a single sensor input, and is not directed to one that can handle a plurality of sensor inputs and that, despite being simple, can perform accurate sensing.

### SUMMARY OF THE INVENTION

It is an object of the present invention to provide a magnetic sensor circuit that includes a magnetism detection circuit adopting a differential circuit configuration, that is less affected by the device offset voltage appearing in a magnetoelectric conversion device such as a Hall device or magnetic resistive device, and that in addition is less affected by the input offset voltage arising in an amplifier. It is also an object of the present invention to provide a semiconductor device having such a magnetic sensor circuit integrated into it, and to provide a magnetic sensor device employing such a semiconductor device.

To achieve the above objects, according to one aspect of the present invention, a magnetic sensor circuit is provided with: a first magnetoelectric conversion device generating, across a first or second pair of terminals, an output voltage commensurate with magnetism-to-be-measured; a second magnetoelectric conversion device generating, across a third or fourth pair of terminals, an output voltage commensurate with the magnetism-to-be-measured; a first selection switch circuit switched between a first switch state in which the first selection switch circuit applies a supply voltage across the first pair of terminals and feeds an output voltage appearing across the second pair of terminals to between a first output terminal and a second output terminal and a second switch state in which the first selection switch circuit applies the supply voltage across the second pair of terminals and feeds an output voltage appearing across the first pair of terminals to between the first output terminal and the second output terminal; a second selection switch circuit switched between a first switch state in which the second selection switch circuit applies the supply voltage across the third pair of terminals and feeds an output voltage appearing across the fourth pair of terminals to between a third output terminal and a fourth output terminal and a second switch state in which the second selection switch circuit applies the supply voltage across the fourth pair of terminals and feeds an output voltage appearing across the third pair of terminals to between the third output terminal and the fourth output terminal; a first amplifier unit that amplifies at a predetermined amplification factor a voltage appearing at the first output terminal and fed to a first amplification input terminal to output a first amplified voltage to a first amplification output terminal and that amplifies at the predetermined amplification factor a voltage appearing at the second output terminal and fed to a second amplification input terminal to output a second amplified voltage to a second amplification output terminal; a second amplifier unit that amplifies at the predetermined amplification factor a voltage appearing at the third output terminal and fed to a third amplification input terminal to output a third amplified voltage to a third amplification output terminal and that amplifies at the predetermined amplification factor a voltage appearing at the fourth output terminal and fed to a fourth amplification input terminal to output a fourth amplified voltage to a fourth amplification output terminal; a comparison unit comparing a first comparison voltage fed to a first comparison input terminal and a second comparison voltage fed to a second comparison input terminal with each other to generate a comparison output if the first comparison voltage is higher than the second comparison voltage; a first capacitor provided between the first amplification output terminal and the first comparison input terminal; a second capacitor provided between the second amplification output terminal and the second comparison input terminal; a third capacitor provided between the third amplification output terminal and the second comparison input terminal; a fourth capacitor provided between the fourth amplification output terminal and the first comparison input terminal; a first switch circuit applying a first reference voltage to the first comparison input terminal in the first switch state; and a second switch circuit applying a second reference voltage to the second comparison input terminal in the first switch state.

Other features, elements, steps, advantages and characteristics of the present invention will become more apparent from the following detailed description of preferred embodiments thereof with reference to the attached drawings.

### BRIEF DESCRIPTION OF THE DRAWINGS

FIG. 1 is a diagram showing the configuration of a magnetic sensor circuit according to a first embodiment of the invention;

FIG. 2 is a diagram showing a first example of the amplifier units;

FIG. 3 is a diagram showing a second example of the amplifier units;

FIG. 4 is a diagram showing the configuration of the reference voltage generation circuit 90;

FIG. 5 is a timing chart illustrating the operation of the magnetic sensor circuit according to the first embodiment of the invention;

FIG. 6 is a diagram showing the configuration of a magnetic sensor circuit according to a second embodiment of the invention;

FIGS. 7A and 7B are diagrams showing examples of application of the magnetic sensor circuit according to the second embodiment of the invention;

FIG. 8 is a timing chart illustrating the operation of the magnetic sensor circuit according to the second embodiment of the invention;

FIG. 9 is a diagram showing the configuration of a magnetic sensor circuit according to a third embodiment of the invention;

FIG. 10 is a diagram showing an example of the amplifier units 30X′ and 30Y′; and

FIG. 11 is a diagram showing the configuration of a conventional magnetic field sensor.

### DETAILED DESCRIPTION OF PREFERRED EMBODIMENTS

Hereinafter, embodiments of magnetic sensor circuits according to the present invention will be described with reference to the accompanying drawings. Magnetic sensor circuits according to the invention find wide application as sensors for detecting the state of magnetism (the intensity of a magnetic field), such as sensors for detecting the folded and unfolded states of a folding-type cellular phone and sensors for detecting the rotational position of a motor. These magnetic sensor circuits incorporate a magnetic sensor device that varies its electric characteristic with the magnetic field applied to it and that yields an output voltage that varies with the variation in the electric characteristic. Examples of such a magnetic sensor device include magnetoelectric conversion devices such as a Hall device and a magnetic resistive device. The embodiments presented below deal with magnetic sensor circuits employing a Hall device.

### First Embodiment

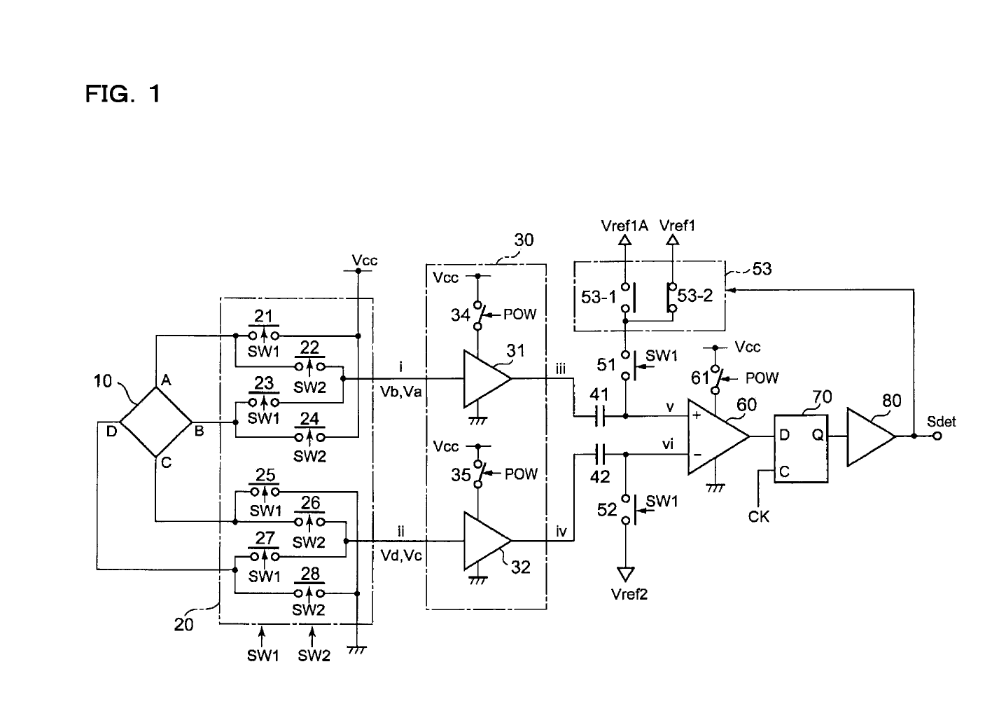

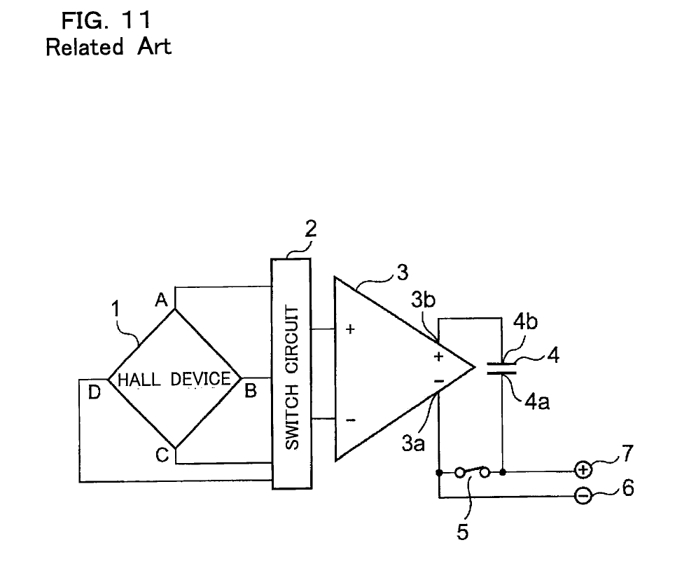

FIGS. 1 to 5 are diagrams showing the configuration of a magnetic sensor circuit according to a first embodiment of the present invention. This embodiment is one which the applicant of the present invention already proposed in Japanese Patent Application No. 2005-230781 (a domestic application claiming the priority date based on a prior domestic application No. 2005-031715). In FIG. 1, as in the conventional example shown in FIG. 11, a Hall device is formed as a plate having a shape that is geometrically equivalent with respect to four terminals A, C, B, and D.

In this Hall device 10, between the Hall voltage that appears across a second pair of terminals (B and D) when the supply voltage Vcc is applied across a first pair of terminals (A and C) and the Hall voltage that appears across the first pair of terminals (C and A) when the supply voltage Vcc is applied across a second pair of terminals (B and D), the effective signal components contained respectively in them—the components commensurate with the intensity of the magnetic field applied to the Hall device 10—are in phase, whereas the device offset components (device offset voltages) contained respectively in them are in opposite phases.

A selection switch circuit 20 switches the way the supply voltage Vcc is applied to the Hall device 10 and the way the Hall voltage is derived from the Hall device 10.

More specifically, the selection switch circuit 20 has switches 21, 23, 25 and 27 that are turned on by a first switch signal SW1, and switches 22, 24, 26, and 28 that are turned on by a second switch signal SW2. The first and second switch signals SW1 and SW2 are so generated that they do not concur and that they are present within the first and second halves, respectively, of a predetermined period during which a power-on signal POW is present. The power-on signal POW is generated intermittently so that, for example, it is present for a predetermined period at a predetermined cycle.

In the first switch state, that is, in the state in which the first switch signal SW1 is present, the supply voltage Vcc is applied to terminal A, terminal C is connected to ground, and a Hall voltage commensurate with the intensity of the magnetic field appears across terminals B and D. Which of the voltages at terminals B and D is higher depends on the direction of the magnetic field applied. Here, it is assumed that the voltage Vb at terminal B is the lower and the voltage Vd at terminal D is the higher. It should be noted that, unless otherwise stated, any voltage mentioned in the course of the description denotes a potential relative to ground.

The switch from the first switch signal SW1 to the second switch signal SW2 takes place instantaneously, and therefore it is assumed that, in the second switch state, the direction of the magnetic field remains the same as in the first switch state. In the second switch state, that is, in the state in which the second switch signal SW2 is present, the supply voltage Vcc is applied to terminal B, terminal D is connected to ground, and a Hall voltage commensurate with the intensity of the magnetic field appears across terminals C and A. The voltage across terminals C and A is such that the voltage Vc at terminal C is the lower, and the voltage Va at terminal A is the higher.

Thus, the voltage at the first output terminal “i” of the selection switch circuit 20 equals the voltage Vb in the first switch state, and equals the voltage Va in the second switch state. On the other hand, the voltage at the second output terminal “ii” of the selection switch circuit 20 equals the voltage Vd in the first switch state, and equals the voltage Vc in the second switch state.

An amplifier unit 30 amplifies the voltage at a first amplification input terminal, which is connected to the first output terminal “i”, at a predetermined amplification factor α with a first amplifier circuit 31; the amplifier unit 30 thereby yields, at a first amplification output terminal “iii”, a first amplified voltage. Since an input offset voltage Voffa1 is present in the first amplifier circuit 31, this input offset voltage Voffa1 is added to the voltage at the first amplification input terminal.

Likewise, the amplifier unit 30 amplifies the voltage at a second amplification input terminal, which is connected to the second output terminal “ii”, at the predetermined amplification factor α with a second amplifier circuit 32; the amplifier unit 30 thereby yields, at a second amplification output terminal “iv”, a second amplified voltage. Since an input offset voltage Voffa2 is present in the second amplifier circuit 32, this input offset voltage Voffa2 is added to the voltage at the second amplification input terminal.

The first and second amplifier circuits 31 and 32 in the amplifier unit 30 receive the supply voltage Vcc through switch circuits 34 ad 35, respectively, that are turned on by the power-on signal POW. Thus, the amplifier unit 30 operates according to the power-on signal POW, that is, intermittently so that, for example, it operates for a predetermined period at a predetermined cycle. In a case where the first and second amplifier circuits 31 and 32 are of a current-driven type, preferably, the switch circuits 34 and 35 are each configured as a current source circuit having a switch function.

A first capacitor 41 is connected between the first amplification output terminal “iii” and the first comparison input terminal “v” of a comparator unit 60. A second capacitor 42 is connected between the second amplification output terminal “iv” and the second comparison input terminal “vi” of the comparator unit 60.

The comparator unit 60 compares a first comparison voltage fed to a first comparison input terminal “v” with a second comparison voltage fed to a second comparison input terminal “vi”, and outputs a comparison output when the first comparison voltage is higher than the second comparison voltage. The comparator unit 60 is configured to have an extremely high input impedance; for example, its input circuit is configured as a MOS transistor circuit. The comparator unit 60 receives the supply voltage through a switch circuit 61 that is turned on by the power-on signal POW. Thus, the comparator unit 60 operates according to the power-on signal POW, that is, intermittently so that, for example, it operates for a predetermined period at a predetermined cycle. The switch circuit 61 may be a current source circuit having a switch function.

To the first comparison input terminal “v” is supplied, through a reference voltage switch circuit 53 and then through a first switch circuit 51 that is turned on by the first switch signal SW1, a first reference voltage Vref1. The reference voltage switch circuit 53 is switched, when the magnetic sensor circuit detects magnetism, by a detection signal Sdet it outputs. When the reference voltage switch circuit 53 is switched, to the first comparison input terminal “v” can also be supplied a modified first reference voltage Vref1A.

To the second comparison input terminal “vi” is supplied, through a second switch circuit 52 that is turned on by the first switch signal SW1, a second reference voltage Vref2. Preferably, the first reference voltage Vref1 is set to be a predetermined level lower than the modified first reference voltage Vref1A, which in turn is set to be a predetermined level lower than the second reference voltage Vref2. As the modified first reference voltage Vref1A, the second reference voltage Vref2 may be used.

By making the voltages supplied to the first and second comparison input terminals “v” and “vi” equal to the first and second reference voltages Vref1 and Vref2 when the comparison output is absent, and making them equal to the modified first reference voltage Vref1A and the second reference voltage Vref2 when the comparison output is present, it is possible to give the operation of the comparator unit 60 a hysteresis characteristic. This allows stable detection. The hysteresis width can easily be varied by adjusting the levels of the first reference voltage Vref1, the modified first reference voltage Vref1A, and the second reference voltage Vref2.

A latch circuit 70 latches the comparison output synchronously with a clock signal CK. Suitable as the latch circuit 70 is a D flip-flop. The latched output of the latch circuit 70 is amplified by a buffer amplifier 80 to produce the detection signal Sdet.

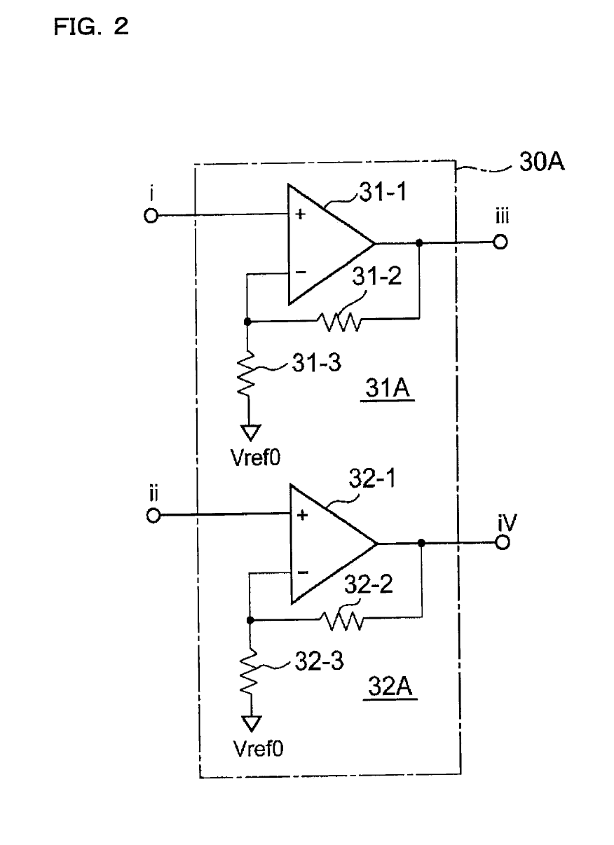

FIG. 2 is a diagram showing a first example of the amplifier unit. The amplifier unit 30A shown in FIG. 2 includes a first amplifier circuit 31A and a second amplifier circuit 32A. In the first amplifier circuit 31A, a feedback resistor 31-2 is connected between the inverting input terminal of an operational amplifier 31-1 and the output terminal “iii”, and a feedback resistor 31-3 is connected between the inverting input terminal of the operational amplifier 31-1 and the reference voltage Vref0. The voltage at the first output terminal “i” is fed to the non-inverting terminal of the operational amplifier 31-1 so as to be amplified by it to produce the first amplified voltage at the first amplification output terminal “iii”. The second amplifier circuit 32A is configured similarly, so that the voltage at the second output terminal “ii” is amplified to produce the second amplified voltage at the second amplification output terminal “iv”.

In the amplifier unit 30A shown in FIG. 2, let the resistance of the feedback resistors 31-2 and 32-2 be R2, and let the resistance of the feedback resistors 31-3 and 32-3 be R1, then the amplification factor a approximately equals R2/R1, assuming that R2>>R1.

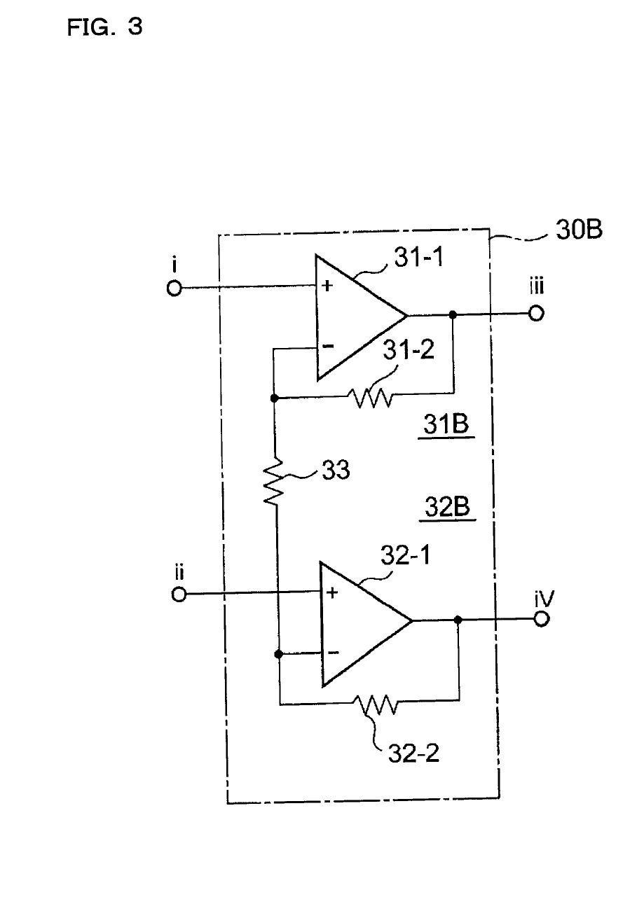

FIG. 3 is a diagram showing a second example of the amplifier unit. The amplifier unit 30B shown in FIG. 3 includes: a first operational amplifier 31-1 that receives at its non-inverting terminal the voltage at the first output terminal “i” and that outputs the first amplification output at the output terminal “iii”; a first feedback resistor 31-2 that is provided between the output terminal “iii” and inverting input terminal of the first operational amplifier 31-1; a second operational amplifier 32-1 that receives at its non-inverting terminal the voltage at the second output terminal “ii” and that outputs the second amplification output at the output terminal “iv”; a second feedback resistor 32-2 that is provided between the output terminal “iv” and inverting input terminal of the second feedback resistor 32-2; and a third feedback resistor 33 that is provided between the inverting input terminal of the first operational amplifier 31-1 and the inverting input terminal of the second operational amplifier 32-1.

Thus, the amplifier unit 30B is so configured that a first and a second amplification circuit 31B and 32B share the third feedback resistor 33; that is, it is configured as a balanced-input, balanced-output amplification circuit. Compared with the amplifier unit 30A shown in FIG. 2, the amplifier unit 30B has the following advantages: it operates with less feedback resistors; it requires no setting of reference voltages, because the reference voltages for the first and second amplifier circuits 31A and 31B are automatically set within the circuits.

Moreover, as a result of the amplifier unit 30B having a unique balanced-input, balanced-output configuration, it offers a high voltage amplification gain. Specifically, let the resistance of the feedback resistors 31-2 and 32-2 be R2, and let the resistance of the third feedback resistor 33 be R1, then the amplification factor o approximately equals 2×R2/R1, assuming that R2>>R1. The doubled amplification factor makes circuit design easy, and also makes it easy to use a Hall device having low sensitivity. In the amplifier units 30A and 30B, the amplification circuits receive their operating supply voltage through the switch circuits 34 and 35 as shown in FIG. 1.

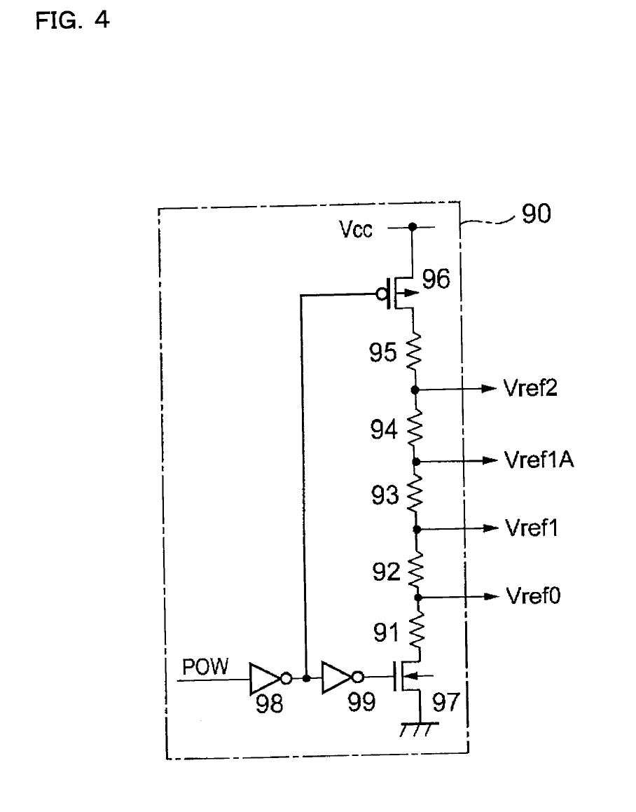

FIG. 4 is a diagram showing the configuration of a reference voltage generation circuit 90. In the reference voltage generation circuit 90 shown in FIG. 4, the supply voltage Vcc is divided with division resistors 91 to 95 to generate the reference voltages Vref0, the first reference voltage Vref1, the modified first reference voltage Vref1A, and the second reference voltage Vref2. These reference voltages are generated when a P-type MOS transistor 96 and an N-type MOS transistor 97 that are respectively provided on the supply voltage Vcc side and the ground side of the division resistors 91 to 95 are on. These MOS transistors 96 and 97 are turned on, through inverters 98 and 99, according to the power-on signal POW. The MOS transistors 96 and 97 may be turned on according to, instead of the power-on signal POW, the first switch signal SW1.

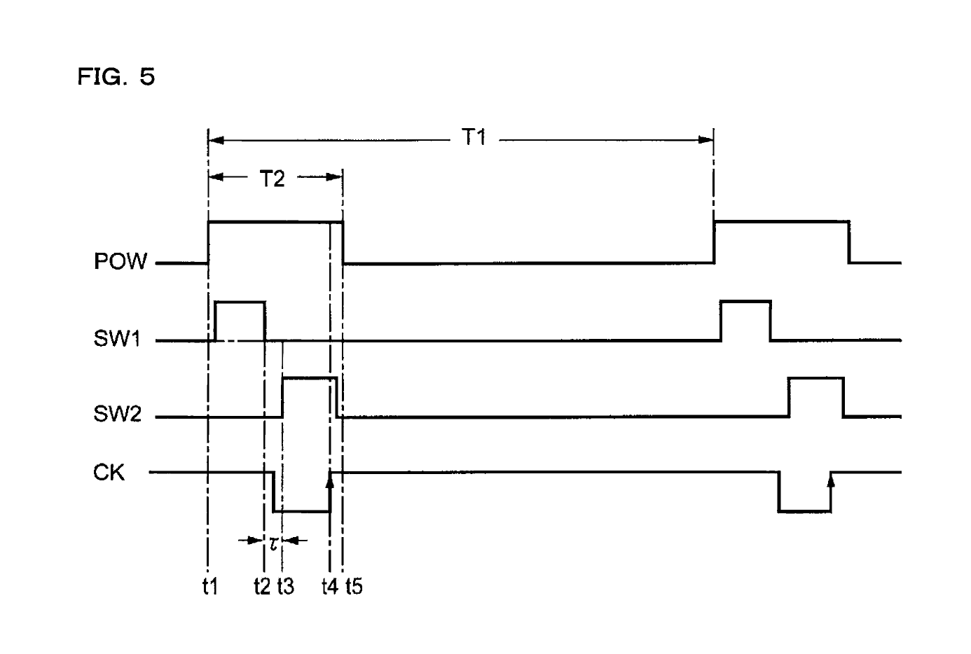

Next, the operation of the magnetic sensor circuit configured as described above will be described with reference also to the timing chart in FIG. 5. The power-on signal POW, the first and second switch signals SW1 and SW2, and the clock signal CK are generated by a control circuit, which will be described later.

The power-on signal POW is so generated as to be present for a predetermined period T2 at every predetermined cycle called a first cycle T1. Thus, the magnetic sensor circuit is supplied with the supply voltage Vcc intermittently to operate. For example, for the purpose of detecting the folded and unfolded states of a cellular phone, the first cycle T1 can be set at 50 ms, and the predetermined period T2 at 25 μs. This greatly reduces the electric power consumption of the cellular phone while ensuring proper detection of the folded and unfolded states. Preferably, the lengths of the first cycle T1 and the predetermined period T2 are set appropriately to suit how the magnetic sensor circuit of the invention is actually used. The magnetic sensor circuit may be operated continuously, instead of intermittently.

At approximately the same time as time point t1 at which the power-on signal POW is applied, the first switch signal SW1 is generated. With the first switch signal SW1 present, in the selection switch circuit 20, the switches 21, 23, 25, and 27 turn on, establishing the first switch state; in addition, the first and second switch circuits 51 and 52 turn on.

In the Hall device 10, the supply voltage Vcc and the ground voltage are applied to a first pair of terminals (A and C) and a Hall voltage appears across a second pair of terminals (B and D). Here, a voltage Vb appears at terminal B, and a voltage Vd appears at terminal D.

At the first amplification output terminal “iii” of the amplifier unit 30, a first amplified voltage α (Vb−Voffa1) appears as a result of the voltage Vb being amplified; at the second amplification output terminal “iv” of the amplifier unit 30, a second amplified voltage α (Vd−Voffa2) appears as a result of the voltage Vd being amplified. Here, α represents the amplification factor of the amplifier unit 30, and Voffa1 and Voffa2 represent the input offset voltages of the first and second amplifier circuits 31 and 32.

In this first switch state, the first and second switch circuits 51 and 52 are on and, assuming that the reference voltage switch circuit 53 is not switched, the switch 53-2 is on. Accordingly, the first reference voltage Vref1 is applied to the first comparison input terminal “v” of the comparator unit 60, and the second reference voltage Vref2 is applied to the second comparison input terminal “vi” of the comparator unit 60.

Thus, the first capacitor 41 is charged to the voltage difference across it, namely Vref1−α (Vb−Voffa1). Likewise, the second capacitor 42 is charged to the voltage difference across it, namely Vref2−α (Vd−Voffa2).

At time point t2, the first switch signal SW1 becomes absent, marking the end of the first switch state. A predetermined short period τ thereafter, at time point t3, the second switch signal SW2 is generated. Securing the predetermined short period τ here creates a period during which the selection switch circuit 20 is in neither of the first and second switch states. With the second switch signal SW2 present, in the selection switch circuit 20, the switches 22, 24, 26, and 28 turn on, establishing the second switch state; on the other hand, the first and second switch circuits 51 and 52 turn off.

Now, in the Hall device 10, the supply voltage Vcc and the ground voltage are applied to the second pair of terminals (B and D) and a Hall voltage appears across the first pair of terminals (C and A). Here, a voltage Vc appears at terminal C, and a voltage Va appears at terminal A.

At the first amplification output terminal “iii” of the amplifier unit 30, a first amplified voltage α (Va−Voffa1) appears as a result of the voltage Va being amplified; at the second amplification output terminal “iv” of the amplifier unit 30, a second amplified voltage α (Vc−Voffa2) appears as a result of the voltage Vc being amplified.

In this second switch state, the first and second switch circuits 51 and 52 are off. Moreover, since the reference voltage switch circuit 53 is not switched yet, the switch 53-2 is still on.

The electric charges with which the first and second capacitors 41 and 42 are charged do not vary but are held, and thus the first and second comparison voltages Vcomp1 and Vcomp2 at the first comparison input terminal “v” and the second comparison input terminal “vi” of the comparator unit 60 are given by formulae (1) and (2) below.

$$\begin{matrix}\begin{matrix}Vcomp 1 = Vref 1 - [ α ( Vb - Voffa 1 ) - α ( Va - Voffa 1 ) ] \\ = Vref 1 - α ( Vb - Va )\end{matrix} & ( 1 ) \\ \begin{matrix}Vcomp 2 = Vref 2 - [ α ( Vd - Voffa 2 ) - α ( Vc - Voffa 2 ) ] \\ = Vref 2 - α ( Vd - Vc )\end{matrix} & ( 2 )\end{matrix}$$

As will be seen from formulae (1) and (2), the first and second comparison voltages Vcomp1 and Vcomp2 do not contain the input offset voltages Voffa1 and Voffa2. That is, the input offset voltages Voffa1 and Voffa2 are cancelled out through the switching between the first and second switch states.

Then, the comparator unit 60 compares the first and second comparison voltages Vcomp1 and Vcomp2 with each other. Specifically, the difference between the first and second comparison voltages Vcomp1 and Vcomp2 is calculated, and, if the first comparison voltage Vcomp1 is higher than the second comparison voltage Vcomp2 (Vcomp1>Vcomp2), the comparator unit 60 generates a comparison output. The comparison performed by the comparator unit 60 is expressed by formula (3) below.
Vcomp1−Vcomp2=Vref1−Vref2−α(Vb−Va)+α(Vd−Vc) (3)

The Hall voltage generated by the Hall device 10 contains a signal component voltage, which is proportional to the intensity of the magnetic field, and a device offset voltage. In the Hall device 10 used in the present invention, between the voltage that appears across terminals B and D in the first switch state and the voltage that appears across terminals C and A in the second switch state, the effective signal components contained respectively in them—the components commensurate with the intensity of the magnetic field—are in phase, whereas the device offset voltages contained respectively in them are in opposite phases.

Let the device offset voltages contained in the voltages Vb, Vd, Va, and Vc be Vboffe, Vdoffe, Vaoffe, and Vcoffe. Then, the 90-degree cancellation formula dictates that Vboffe−Vdoffe=Vaoffe−Vcoffe. Rearranging this formula gives formula (4) below.
Vboffe−Vaoffe=Vdoffe−Vcoffe (4)

Formula (4) shows that the comparison between the first and second comparison voltages Vcomp1 and Vcomp2 according to formula (3) cancels the device offset voltages out.

In this way, the device offset voltages in the Hall device 10 and the input offset voltages in the amplifier unit 30 are all cancelled out by the comparison by the comparator unit 60.

Next, at time point t4, the clock signal CK rises. At the rising edge of the clock signal CK, the latch circuit 70 latches the comparison output from the comparator unit 60. When the comparison output is latched, the buffer amplifier 80 generates a detection signal Sdet. Then, at time point t5, the power-on signal POW becomes absent and, at approximately the same time, the second switch signal SW2 becomes absent. Incidentally, here, the second switch signal SW2 is formed by inverting and delaying the clock signal CK.

In the second switch state, if the first comparison voltage Vcomp1 is lower than the second comparison voltage Vcomp2, no comparison output is generated (i.e., it remains at L level), and thus no detection signal Sdet is generated. In contrast, if the first comparison voltage Vcomp1 is higher than the second comparison voltage Vcomp2, a comparison output is generated (i.e., it turns to H level), and thus a detection signal Sdet is generated.

The detection signal Sdet generated here switches the reference voltage switch circuit 53 so that the switch 53-2 turns off and the switch 53-1 turns on. This causes the modified first reference voltage Vref1A to be applied to the first comparison input terminal “v” of the comparator unit 60 in the first switch state. Accordingly, during a predetermined period T2 in the next cycle, the threshold level of the comparison operation by the comparator unit 60 is lower. Thus, the comparator unit 60 operates with hysteresis. The hysteresis width equals Vref1A−Vref1, and can be set simply by setting the first reference voltage Vref1 and the modified first reference voltage Vref1A. This makes design and adjustment easy.

Moreover, in the present invention, in the first switch state, the first and second capacitors 41 and 42 are charged with electric charges up to predetermined levels so that the input voltage reference levels of the comparator unit 60 are set at the first and second reference voltages Vref1 and Vref2 having predetermined levels. By setting these first and second reference voltages Vref1 and Vref2 to be as close as possible to the midpoint voltage (Vcc/2) of the supply voltage Vcc, it is possible to obtain a wide input dynamic range.

Moreover, the supply of the supply voltage Vcc to main units, such as the amplifier unit 30 and the comparator unit 60, takes place intermittently at every first cycle T1, and this intermittent operation combined with the latch operation according to the detection signal Sdet helps reduce electric power consumption and ensure stable detection of magnetism.

With reduced electric power consumption thanks to intermittent operation combined with stable detection of magnetism, the magnetic sensor circuit of the invention is particularly suitable as a sensor circuit for use in portable terminals (such as folding-type and rotary-type cellular phones) operating from a battery or the like.

The description has proceeded assuming that the magnetic field applied to the Hall device 10 points in one certain direction; quite naturally, in a case where the magnetic field points in the opposite direction, the generated Hall voltage has the opposite polarity, in which case the circuit is configured to suit the polarity of the Hall voltage.

### Second Embodiment

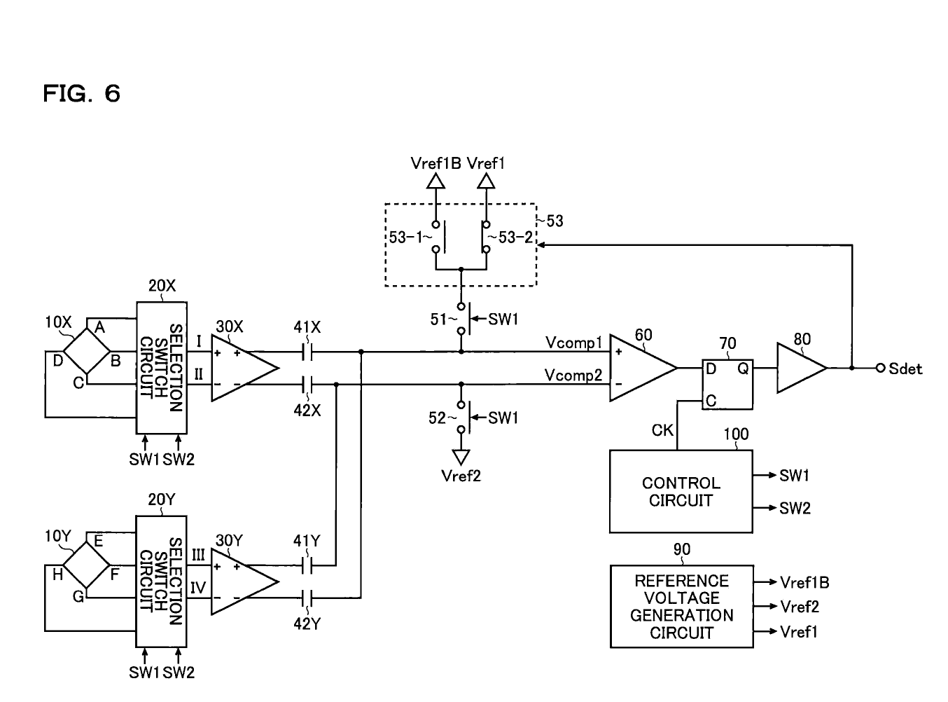

FIG. 6 is a diagram showing the configuration of a magnetic sensor circuit according to a second embodiment of the present invention.

The magnetic sensor circuit according to the second embodiment includes a first Hall device 10X, a second Hall device 10Y, a first selection switch circuit 20X, a second selection switch circuit 20Y, a first amplifier unit 30X, a second amplifier unit 30Y, a first capacitor 41X, a second capacitor 42X, a third capacitor 41Y, a fourth capacitor 42Y, a first switch circuit 51, a second switch circuit 52, a reference voltage switch circuit 53, a comparison unit 60, a latch circuit 70, a buffer amplifier 80, a reference voltage generation circuit 90, and a control circuit 100.

The first Hall device 10X generates, across a first pair of terminals (A and C) or across a second pair of terminals (B and D), an output voltage commensurate with the magnetism applied to it.

The second Hall device 10Y is arranged side by side with the first Hall device 10X, and generates, across a third pair of terminals (E and G) or across a fourth pair of terminals (F and H), an output voltage commensurate with the magnetism applied to it.

According to a first and a second switch signals SW1 and SW2, the first selection switch circuit 20X is switched between a first switch state and a second switch state. In the first switch state, the first selection switch circuit 20X applies a supply voltage Vcc across the first pair of terminals (A and C), and feeds the output voltage appearing across the second pair of terminals (B and D) to between a first and a second output terminal I and II. In the second switch state, the first selection switch circuit 20X applies the supply voltage Vcc across the second pair of terminals (B and D), and feeds the output voltage appearing across the first pair of terminals (A and C) to between the first and second output terminals I and II.

According to the first and second switch signals SW1 and SW2, the second selection switch circuit 20Y is switched between a first switch state and a second switch state. In the first switch state, the second selection switch circuit 20Y applies the supply voltage Vcc across the third pair of terminals (E and G), and feeds the output voltage appearing across the fourth pair of terminals (F and H) to between a third and a fourth output terminal III and IV. In the second switch state, the second selection switch circuit 20Y applies the supply voltage Vcc across the fourth pair of terminals (F and H), and feeds the output voltage appearing across the third pair of terminals (E and G) to between the third and fourth output terminals III and IV.

The internal configuration and operation of the first and second selection switch circuits 20X and 20Y are similar to those of the switch circuit 20 shows in FIG. 1 and described previously, and therefore no detailed explanation of them will be repeated.

The first amplifier unit 30X amplifies the voltage appearing at the first output terminal I and fed to a first amplification input terminal (+) by a predetermined amplification factor α to output a first amplified voltage to a first amplification output terminal (+). Moreover, the first amplifier unit 30X amplifies the voltage appearing at the second output terminal II and fed to a second amplification input terminal (−) by the predetermined amplification factor α to output a second amplified voltage to a second amplification output terminal (−).

The second amplifier unit 30Y amplifies the voltage appearing at the third output terminal III and fed to a third amplification input terminal (+) by the predetermined amplification factor α to output a third amplified voltage to a third amplification output terminal (+). Moreover, the second amplifier unit 30Y amplifies the voltage appearing at the fourth output terminal IV and fed to a fourth amplification input terminal (−) by the predetermined amplification factor α to output a fourth amplified voltage to a fourth amplification output terminal (−).

The internal configuration and operation of the first and second amplifier units 30X and 30Y may be similar to those of the amplifier unit 30A shown in FIG. 2 or the amplifier unit 30B shown in FIG. 3, both described previously. It is particularly preferable that, like the amplifier unit 30B shown in FIG. 3, the first and second amplifier units 30X and 30Y be each configured as a balanced-input, balanced-output type. With this configuration, it is possible to obtain a high voltage amplification gain. Moreover, it is then unnecessary to prepare reference voltages in the first and second amplifier units 30X and 30Y, and therefore it is unnecessary to adjust reference voltages to the output voltages of the first and second Hall devices 10X and 10Y. Furthermore, it is possible to reduce the number of feedback resistors needed in the first and second amplifier units 30X and 30Y.

The first capacitor 41X is provided between the first amplification output terminal (+) of the first amplifier unit 30X and a first comparison input terminal (+) of the comparison unit 60.

The second capacitor 42X is provided between the second amplification output terminal (−) of the first amplifier unit 30X and a second comparison input terminal (−) of the comparison unit 60.

The third capacitor 41Y is provided between the third amplification output terminal (+) of the second amplifier unit 30Y and the second comparison input terminal (−) of the comparison unit 60.

The fourth capacitor 42Y is provided between the fourth amplification output terminal (−) of the second amplifier unit 30Y and the first comparison input terminal (+) of the comparison unit 60.

The comparison unit 60 compares the first comparison voltage Vcomp1 fed to the first comparison input terminal (+) and the second comparison voltage Vcomp2 fed to the second comparison input terminal (−) with each other and, if the first comparison voltage Vcomp1 is higher than the second comparison voltage Vcomp2, the comparison unit 60 generates a comparison output (shifts its logic level from low level to high level).

The control circuit 100 outputs the first and second switch signal SW1 and SW2 and a clock signal CK. The clock signal CK is a pulse signal that is fed to the clock input terminal of the latch circuit 70, and rises at a predetermined time point in the second switch state mentioned above.

The latch circuit 70 latches the comparison output of the comparison unit 60 at the rising edge of the clock signal CK.

The buffer amplifier 80 amplifies the output of the latch circuit 70 to produce a detection signal Sdet.

As described above, the magnetic sensor circuit according to the second embodiment of the invention has a configuration in which the offset cancellation technology of the first embodiment is applied to a magnetic sensor circuit having two Hall devices. In this configuration, by use of the first and second selection switch circuits 20X and 20Y, the Hall voltages obtained from the first and second Hall devices 10X and 10Y are outputted while the first and second states are switched; the first and second amplifier units 30X and 30Y are each made to operate differentially, and when the difference between the outputs from them is greater than the set hysteresis width, the output logic level of the detection signal Sdet is shifted.

With this configuration, when judging which of the outputs of the first and second Hall devices 10X and 10Y is higher, it is possible to sufficiently reduce the influence of the device offset voltages in the first and second Hall devices 10X and 10Y and the input offset voltages in the first and second amplifier units 30X and 30Y. Thus, it is possible to enhance the detection accuracy of the magnetic sensor circuit without requiring repair, stress management, etc.

To the first comparison input terminal (+) of the comparison unit 60 is supplied, through the reference voltage switch circuit 53 and then through the first switch circuit 51 that is turned on by the first switch signal SW1, a first reference voltage Vref1. The reference voltage switch circuit 53 is switched, when the magnetic sensor circuit detects magnetism, by a detection signal Sdet it outputs. When the reference voltage switch circuit 53 is switched, to the first comparison input terminal (+) of the comparison unit 60 can also be supplied a modified first reference voltage Vref1B. On the other hand, to the second comparison input terminal (−) of the comparison unit 60 is supplied, through the second switch circuit 52 that is turned on by the first switch signal SW1, a second reference voltage Vref2.

Here, in the reference voltage generation circuit 90, the first reference voltage Vref1 is set to be a predetermined level lower than the second reference voltage Vref2, and the modified first reference voltage Vref1B is set to be a predetermined level higher than the second reference voltage Vref2. In the magnetic sensor circuit configured as described above, according to the latch output of the latch circuit 70 (i.e., the detection signal Sdet), the first reference voltage Vref1 is switched to the modified first reference voltage Vref1B so that the level relationship between the voltages applied to the first comparison input terminal (+) and the second comparison input terminal (−) of the comparison unit 60 is reversed.

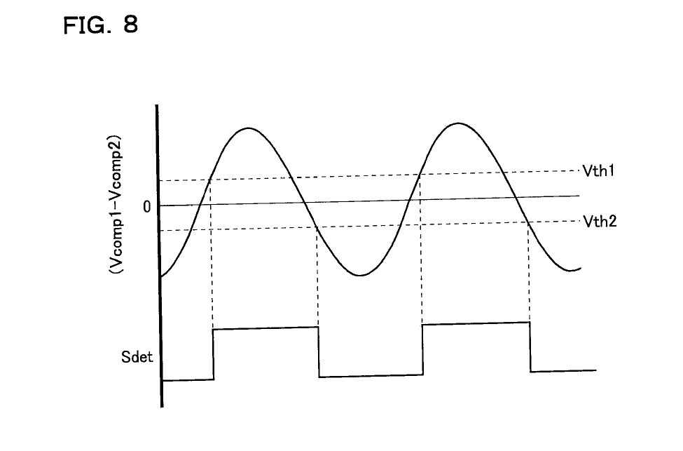

This gives the operation of the comparison unit 60 an appropriate hysteresis characteristic (one across zero as shown in FIG. 8, which will be described later), and thus allows stable detection of magnetism. Moreover, the hysteresis width can be altered easily by adjusting the levels of the first reference voltage Vref1, the modified first reference voltage Vref1B, and the second reference voltage Vref2. Although the description above deals with a configuration in which the voltage level of the first reference voltage Vref1 is switched, this is in no way meant to limit the configuration with which to practice the present invention; instead, any other switching method may be adopted so long as, according to the latch output of the latch circuit 70 (i.e., the detection signal Sdet), the level relationship between the voltages applied to the first comparison input terminal (+) and the second comparison input terminal (−) of the comparison unit 60 is reversed.

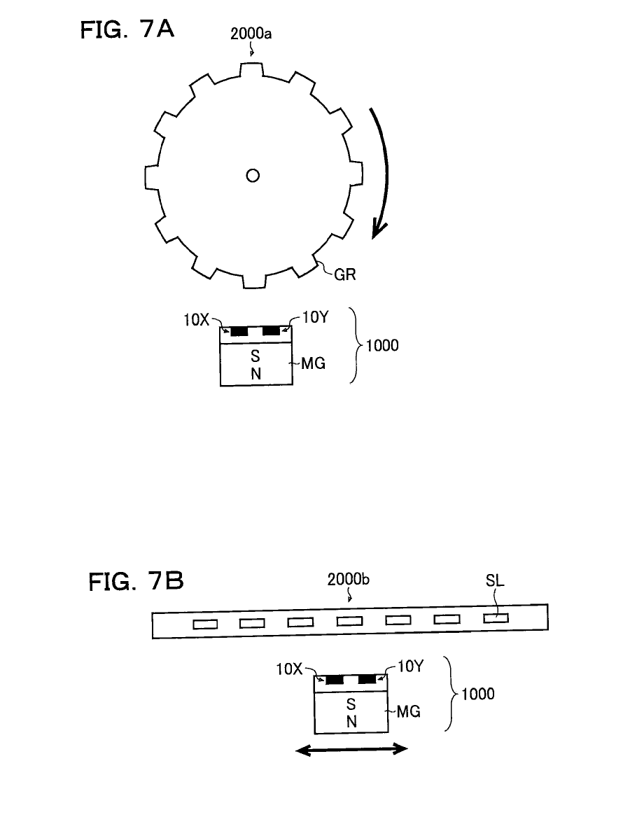

FIGS. 7A and 7B are diagrams showing examples of application of the magnetic sensor circuit according to the second embodiment of the invention.

The magnetic sensor circuit according to the second embodiment of the invention can be applied to a magnetic sensor device 1000 for detecting, as shown in FIG. 7A, the rotation speed and rotation angle of a target (gear) 2000a in rotating movement or, as shown in FIG. 7B, the sliding speed and sliding distance of a target (slit rail) 2000b in linear movement. Here, it is assumed that the targets 2000a and 2000b are both formed of a ferromagnetic material (such as iron). It should be noted that FIG. 7B shows a case in which, instead of the target 2000b being in linear movement, it is the magnetic sensor device 1000 that is in linear movement.

The magnetic sensor device 1000 mentioned above includes: a semiconductor device having the magnetic sensor circuit shown in FIG. 6 integrated into it; and a magnet MG provided on the back of the semiconductor device to face away from the target 2000a or 2000b.

In the case shown in FIG. 7A, as the target 2000a rotates, the distance between the gear teeth GR of the target 2000a and the first and second Hall devices 10X and 10Y varies. Thus, as shown in FIG. 8, the difference between the intensities detected by the two Hall devices (i.e., Vcomp1−Vcomp2) varies cyclically, and accordingly the output logic level of the detection signal Sdet varies cyclically. Thus, by monitoring the detection signal Sdet, it is possible to accurately detect the rotation speed and rotation angle of the target 2000a.

In the case shown in FIG. 7B, as the magnetic sensor device 1000 slides, the distance between the slits SL in the target 2000b and the first and second Hall devices 10X and 10Y varies. Thus, as in the case just described, as shown in FIG. 8, the difference between the intensities detected by the two Hall devices (i.e., Vcomp1−Vcomp2) varies cyclically, and accordingly the output logic level of the detection signal Sdet varies cyclically. Thus, by monitoring the detection signal Sdet, it is possible to accurately detect the sliding speed and sliding distance of the target 2000b.

The magnetic sensor device 1000 shown in FIGS. 7A and 7B is not of the type that requires a target to be located between a Hall device and a magnet. This leads to increased arrangement flexibility and reduced arrangement space.

Forming the first and second Hall devices 10X and 10Y on a single silicon substrate facilitates the assembly of a set incorporating the magnetic sensor device 1000, and also helps reduce the difference in sensitivity between the two Hall devices. It is, however, not absolutely necessary to form the first and second Hall devices 10X and 10Y on a single silicon substrate; forming them on separate chips makes it easy to adjust the arrangement interval between the first and second Hall devices 10X and 10Y to suit the pitch of the gear GR or the slits SL.

### Third Embodiment

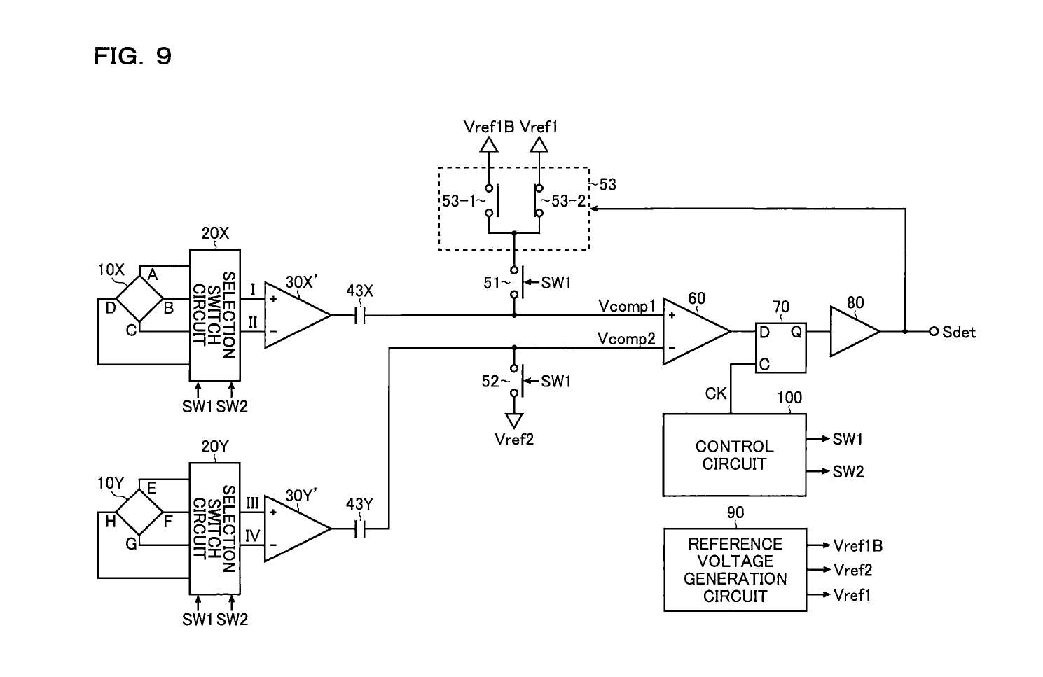

FIG. 9 is a diagram showing the configuration of a magnetic sensor circuit according to a third embodiment of the present invention.

As shown in FIG. 9, the magnetic sensor circuit according to the third embodiment includes, instead of the first and second amplifier units 30X and 30Y of the two-input, two-output type, a first and a second amplifier unit 30X′ and 30Y′ of the two-input, one-output type. The first amplifier unit 30X′ amplifies with a predetermined amplification factor a the difference between the voltage appearing at a first output terminal I and fed to a first amplification input terminal (+) and the voltage appearing at a second output terminal II and fed to a second amplification input terminal (−) to output a first amplified voltage to a first amplification output terminal (+). The second amplifier unit 30Y′ amplifies with the predetermined amplification factor α the difference between the voltage appearing at a third output terminal III and fed to a third amplification input terminal (+) and the voltage appearing at a fourth output terminal IV and fed to a fourth amplification input terminal (−) to output a second amplified voltage to a second amplification output terminal (+). In addition, a first capacitor 43X is provided between the first amplification output terminal (+) of the first amplifier unit 30X′ and the first comparison input terminal (+) of the comparison unit 60, and a second capacitor 43Y is provided between the second amplification output terminal (−) of the second amplifier unit 30Y′ and the second comparison input terminal (−) of the comparison unit 60.

With this configuration, it is possible to halve the number of operational amplifiers, and also the number of capacitors provided in the succeeding stage, needed in the first and second amplifier units 30X′ and 30Y′, and thus it is possible to reduce the circuit scale and cost of the magnetic sensor circuit.

In a case where it is necessary to adjust the arrangement interval between the first and second Hall devices 10X′ and 10Y′, it is preferable that the second Hall device 10Y, the second selection switch circuit 20Y, and the second amplifier unit 30Y′ be integrated into a single semiconductor device and the rest of the circuit into another so that, by wire-bonding the two semiconductor devices together, a magnetic sensor device is formed. With this configuration, compared with in a case where a similar configuration is adopted in the second embodiment, it is possible to adjust the arrangement interval between the first and second Hall devices 10X′ and 10Y′ easily while minimizing the need for wire-bonding.

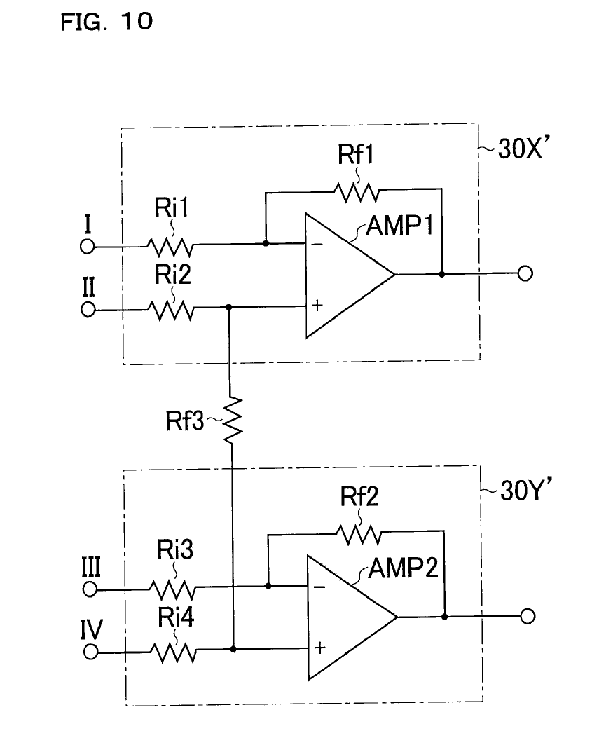

FIG. 10 is a diagram showing an example of the first and second amplifier units 30X′ and 30Y′.

As shown in FIG. 10, in the magnetic sensor circuit according to the third embodiment, the first amplifier unit 30X′ includes: a first input resistor Ri1 of which one end is connected to the first output terminal I; a second input resistor Ri2 of which one end is connected to the second output terminal II; a first operational amplifier AMP1 of which the inverting input terminal (−) is connected to the other end of the first input resistor Ri1 and of which the non-inverting input terminal (+) is connected to the other end of the second input resistor Ri2, the first operational amplifier AMP1 outputting the first amplified voltage at its output terminal; and a first feedback resistor Rf1 provided between the output terminal and the of the first operational amplifier AMP1. The second amplifier unit 30Y′ includes: a third input resistor Ri3 of which one end is connected to the third output terminal III; a fourth input resistor Ri4 of which one end is connected to the fourth output terminal IV; a second operational amplifier AMP2 of which the inverting input terminal (−) is connected to the other end of the third input resistor Ri3 and of which the non-inverting input terminal (+) is connected to the other end of the fourth input resistor Ri4, the second operational amplifier AMP2 outputting the second amplified voltage at its output terminal; and a second feedback resistor Rf2 provided between the output terminal and the inverting input terminal (−) of the second operational amplifier AMP2. In addition, a third feedback resistor Rf3 is provided between the non-inverting input terminal (+) of the first operational amplifier AMP1 and the non-inverting input terminal (+) of the second operational amplifier AMP2.

With this configuration, it is possible to obtain a high voltage amplification gain. Moreover, there is no need to prepare reference voltages in the first and second amplifier units 30X′ and 30Y′, and therefore it is unnecessary to adjust reference voltages to the output voltages of the first and second Hall devices 10X and 10Y. It is also possible to reduce the number of feedback resistors needed in the first and second amplifier units 30X′ and 30Y′.

Incidentally, in a case where amplifier units of the two-input, one-output type are adopted, for higher amplification accuracy, it is preferable to match the input resistors Ri1 to Ri4 and the feedback resistors Rf1 to Rf2.

The application of the present invention is not limited to magnetic sensor circuits; it may be applied to any sensor circuit comprising: a first and a second analog sensor circuit each outputting a plurality of outputs; a first and a second amplifier respectively amplifying the plurality of outputs of the analog sensor circuits; a comparator receiving coupled results of the plurality of outputs of the first and second amplifiers to compare the outputs; and a hysteresis circuit giving hysteresis to the outputs of the first and second amplifiers according to the output of the comparator, wherein there are provided capacitors respectively connected in series between the outputs of the first and second amplifiers and the inputs of the comparator, the outputs of the first and second amplifiers are coupled between the capacitors and the comparator, and the voltage for producing the hysteresis is fed to between the capacitors and the inputs of the comparator to produce a hysteresis characteristic across zero. Here, the first and second amplifiers may each include a plurality of amplifying means for respectively amplifying and then outputting the plurality of outputs from the corresponding analog sensor circuit. With this configuration, it is possible to perform accurate sensing with respect to a plurality of sensor inputs with a simple configuration.

The present invention offers the following benefits. According to the present invention, the first and second amplifier units each operate differentially. This helps satisfactorily reduce the device offset voltages in magnetoelectric conversion devices (such as Hall devices or magnetic resistive devices) and the input offset voltages in the first and second amplifier units.

Moreover, the first and second capacitors, and the third and fourth capacitors, are charged up to predetermined levels in the first switch state so that thereby the input voltage reference levels of the comparison unit are set at predetermined levels. This helps obtain a wide input dynamic range.

Moreover, the first and second amplification units are given a unique balanced-input, balanced-output configuration, and this offers a high voltage amplification gain. Thus, there is no need to prepare reference voltages in the first and second amplification units, and thus there is no need to adjust reference voltages to the output voltages of magnetoelectric conversion devices. It is also possible to reduce the number of feedback resistors needed.

Moreover, by making a first and a second reference voltage fed to the comparison unit different, and changing the reference voltages according to latch operation based on a comparison output, it is possible to give the comparison unit a hysteresis characteristic. The hysteresis width can also be adjusted by appropriately setting the level by which the first and second reference voltages are different (the level by which one is higher or lower than the other), and this makes design and adjustment easy.

While the present invention has been described with respect to preferred embodiments, it will be apparent to those skilled in the art that the disclosed invention may be modified in numerous ways and may assume many embodiments other than those specifically set out and described above. Accordingly, it is intended by the appended claims to cover all modifications of the present invention which fall within the true spirit and scope of the invention.

What is claimed is:

1. A magnetic sensor circuit comprising:
a first magnetoelectric conversion device generating, across a first or second pair of terminals, an output voltage commensurate with magnetism-to-be-measured;
a second magnetoelectric conversion device generating, across a third or fourth pair of terminals, an output voltage commensurate with the magnetism-to-be-measured;
a first selection switch circuit switched between
a first switch state in which the first selection switch circuit applies a supply voltage across the first pair of terminals and feeds an output voltage appearing across the second pair of terminals to between a first output terminal and a second output terminal and
a second switch state in which the first selection switch circuit applies the supply voltage across the second pair of terminals and feeds an output voltage appearing across the first pair of terminals to between the first output terminal and the second output terminal;
a second selection switch circuit switched between
a first switch state in which the second selection switch circuit applies the supply voltage across the third pair of terminals and feeds an output voltage appearing across the fourth pair of terminals to between a third output terminal and a fourth output terminal and
a second switch state in which the second selection switch circuit applies the supply voltage across the fourth pair of terminals and feeds an output voltage appearing across the third pair of terminals to between the third output terminal and the fourth output terminal;
a first amplifier unit
that amplifies at a predetermined amplification factor a voltage appearing at the first output terminal and fed to a first amplification input terminal to output a first amplified voltage to a first amplification output terminal and
that amplifies at the predetermined amplification factor a voltage appearing at the second output terminal and fed to a second amplification input terminal to output a second amplified voltage to a second amplification output terminal;
a second amplifier unit
that amplifies at the predetermined amplification factor a voltage appearing at the third output terminal and fed to a third amplification input terminal to output a third amplified voltage to a third amplification output terminal and
that amplifies at the predetermined amplification factor a voltage appearing at the fourth output terminal and fed to a fourth amplification input terminal to output a fourth amplified voltage to a fourth amplification output terminal;
a comparison unit comparing a first comparison voltage fed to a first comparison input terminal and a second comparison voltage fed to a second comparison input terminal with each other to generate a comparison output if the first comparison voltage is higher than the second comparison voltage;
a first capacitor provided between the first amplification output terminal and the first comparison input terminal;
a second capacitor provided between the second amplification output terminal and the second comparison input terminal;
a third capacitor provided between the third amplification output terminal and the second comparison input terminal;
a fourth capacitor provided between the fourth amplification output terminal and the first comparison input terminal;
a first switch circuit applying a first reference voltage to the first comparison input terminal in the first switch state; and
a second switch circuit applying a second reference voltage to the second comparison input terminal in the first switch state.

2. The magnetic sensor circuit according to claim 1,
wherein the second reference voltage differs from the first reference voltage by a predetermined voltage so that the comparison unit operates with a predetermined threshold level.

3. The magnetic sensor circuit according to claim 1, wherein
the first amplifier unit comprises:
a first operational amplifier
receiving at a non-inverting input terminal thereof the voltage at the first output terminal and
outputting at an output terminal thereof the first amplified voltage;
a first feedback resistor provided between the output terminal and inverting input terminal of the first operational amplifier;
a second operational amplifier
receiving at a non-inverting input terminal thereof the voltage at the second output terminal and
outputting at an output terminal thereof the second amplified voltage;
a second feedback resistor provided between the output terminal and inverting input terminal of the second operational amplifier; and
a third feedback resistor provided between the inverting input terminal of the first operational amplifier and the inverting input terminal of the second operational amplifier, and
the second amplifier unit comprises:
a third operational amplifier
receiving at a non-inverting input terminal thereof the voltage at the third output terminal and
outputting at an output terminal thereof the third amplified voltage;
a fourth feedback resistor provided between the output terminal and inverting input terminal of the third operational amplifier;
a fourth operational amplifier
receiving at a non-inverting input terminal thereof the voltage at the fourth output terminal and
outputting at an output terminal thereof the fourth amplified voltage;
a fifth feedback resistor provided between the output terminal and inverting input terminal of the fourth operational amplifier; and
a sixth feedback resistor provided between the inverting input terminal of the third operational amplifier and the inverting input terminal of the fourth operational amplifier, and

4. The magnetic sensor circuit according to claim 1, further comprising:
a latch circuit latching the comparison output from the comparison unit synchronously with a clock signal to yield a latch output,
wherein the clock signal is generated at a predetermined time point in the second switch state.

5. The magnetic sensor circuit according to claim 4,
wherein at least one of the first and second reference voltages is so changed that, according to the latch output, a level relationship between the voltages applied to the first and second comparison input terminals is reversed.

6. A magnetic sensor circuit comprising:
a first magnetoelectric conversion device generating, across a first or second pair of terminals, an output voltage commensurate with magnetism-to-be-measured;
a second magnetoelectric conversion device generating, across a third or fourth pair of terminals, an output voltage commensurate with the magnetism-to-be-measured;
a first selection switch circuit switched between
a first switch state in which the first selection switch circuit applies a supply voltage across the first pair of terminals and feeds an output voltage appearing across the second pair of terminals to between a first output terminal and a second output terminal and
a second switch state in which the first selection switch circuit applies the supply voltage across the second pair of terminals and feeds an output voltage appearing across the first pair of terminals to between the first output terminal and the second output terminal;
a second selection switch circuit switched between
a first switch state in which the second selection switch circuit applies the supply voltage across the third pair of terminals and feeds an output voltage appearing across the fourth pair of terminals to between a third output terminal and a fourth output terminal and
a second switch state in which the second selection switch circuit applies the supply voltage across the fourth pair of terminals and feeds an output voltage appearing across the third pair of terminals to between the third output terminal and the fourth output terminal;
a first amplifier unit that amplifies at a predetermined amplification factor a difference between a voltage appearing at the first output terminal and fed to a first amplification input terminal and a voltage appearing at the second output terminal and fed to a second amplification input terminal to output a first amplified voltage to a first amplification output terminal;
a second amplifier unit that amplifies at the predetermined amplification factor a difference between a voltage appearing at the third output terminal and fed to a third amplification input terminal and a voltage appearing at the fourth output terminal and fed to a fourth amplification input terminal to output a second amplified voltage to a second amplification output terminal;
a comparison unit comparing a first comparison voltage fed to a first comparison input terminal and a second comparison voltage fed to a second comparison input terminal with each other to generate a comparison output if the first comparison voltage is higher than the second comparison voltage;
a first capacitor provided between the first amplification output terminal and the first comparison input terminal;
a second capacitor provided between the second amplification output terminal and the second comparison input terminal;
a first switch circuit applying a first reference voltage to the first comparison input terminal in the first switch state; and
a second switch circuit applying a second reference voltage to the second comparison input terminal in the first switch state.

7. The magnetic sensor circuit according to claim 6,
wherein the second reference voltage differs from the first reference voltage by a predetermined voltage so that the comparison unit operates with a predetermined threshold level.

8. The magnetic sensor circuit according to claim 6, wherein
the first amplifier unit comprises:
a first input resistor of which one end is connected to the first output terminal;
a second input resistor of which one end is connected to the second output terminal;
a first operational amplifier
having an inverting input terminal thereof connected to another end of the first input resistor,
having a non-inverting input terminal thereof connected to another end of the second input resistor, and
outputting at an output terminal thereof the first amplified voltage; and
a first feedback resistor provided between the output terminal and inverting input terminal of the first operational amplifier,
the second amplifier unit comprises:
a third input resistor of which one end is connected to the third output terminal;
a fourth input resistor of which one end is connected to the fourth output terminal;
a second operational amplifier
having an inverting input terminal thereof connected to another end of the third input resistor,
having a non-inverting input terminal thereof connected to another end of the fourth input resistor, and
outputting at an output terminal thereof the second amplified voltage; and
a second feedback resistor provided between the output terminal and inverting input terminal of the second operational amplifier, and
a third feedback resistor is provided between the non-inverting input terminal of the first operational amplifier and the non-inverting input terminal of the second operational amplifier.

9. The magnetic sensor circuit according to claim 6, further comprising:
a latch circuit latching the comparison output from the comparison unit synchronously with a clock signal to yield a latch output,
wherein the clock signal is generated at a predetermined time point in the second switch state.

10. The magnetic sensor circuit according to claim 9,
wherein at least one of the first and second reference voltages is so changed that, according to the latch output, a level relationship between the voltages applied to the first and second comparison input terminals is reversed.

11. A semiconductor device having a magnetic sensor circuit according to claim 1 integrated thereinto.

12. A semiconductor device having a magnetic sensor circuit according to claim 6 integrated thereinto.

13. A magnetic sensor device comprising:
a semiconductor device according to claim 11; and
a magnet provided on a back of the semiconductor device to face away from a target.

14. A magnetic sensor device comprising:
a semiconductor device according to claim 12; and
a magnet provided on a back of the semiconductor device to face away from a target.

15. A sensor circuit comprising:
first and second analog sensor circuits each yielding a plurality of outputs;
first and second amplifiers each amplifying the plurality of outputs of one of the first and second analog sensor circuits;
a comparator receiving coupled results of a plurality of outputs of the first and second amplifiers;
a hysteresis circuit feeding a voltage for giving hysteresis to the outputs of the first and second amplifiers; and
capacitors respectively connected in series between the outputs of the first and second amplifiers and inputs of the comparator,
wherein the outputs of the first and second amplifiers are coupled between the capacitors and the comparator, and the voltage for giving hysteresis is fed to between the capacitors and the inputs of the comparator to produce a hysteresis characteristic across zero.

16. The sensor circuit according to claim 15,
wherein the first and second amplifiers each include a plurality of amplifying means for respectively amplifying and outputting the plurality of outputs of the corresponding analog sensor circuit.

17. The sensor circuit according to claim 15,
wherein the analog sensor circuits comprise:
a magnetoelectric conversion device generating, at a first or second pair of terminals, an output voltage commensurate with magnetism; and
a selection switch circuit switched between
a first switch state in which the selection switch circuit applies a supply voltage to the first pair of terminals and feeds an output voltage appearing across the second pair of terminals to a first output terminal and a second output terminal and
a second switch state in which the selection switch circuit applies the supply voltage to the second pair of terminals and feeds an output voltage appearing across the first pair of terminals to the first output terminal and the second output terminal.
